(19) United States
(12) Patent Application Publication
(10) Pub. No.: US 2025/0347748 A1
(43) Pub. Date: Nov. 13, 2025

(54) SYSTEM FOR INSPECTING BATTERY AND INSPECTING METHOD OF BATTERY

(71) Applicant: SK On Co., Ltd., Seoul (KR)

(72) Inventors: Yu Ri SONG, Daejeon (KR); Tae Gyun KIM, Daejeon (KR); Ung Bae PARK, Daejeon (KR); Byoung Hak LEE, Daejeon (KR); Jung Taek LIM, Daejeon (KR); Young Jin JANG, Daejeon (KR); Jung Soo CHANG, Daejeon (KR)

(21) Appl. No.: 19/203,171

(22) Filed: May 9, 2025

(30) Foreign Application Priority Data
May 9, 2024 (KR) 10-2024-0061309
Nov. 12, 2024 (KR) 10-2024-0160398
Apr. 22, 2025 (KR) 10-2025-0052385

(51) Int. Cl. G01R 31/385; H01M 10/42; H01M 50/105

(52) U.S. Cl. CPC G01R 31/3865; H01M 10/4285; H01M 50/105

(57) ABSTRACT

The present disclosure relates to a system for inspecting battery and an inspecting method of battery, wherein the system for inspecting battery may comprise a station unit where a battery to be inspected is disposed; and an inspection unit configured to contact a current conductive member with an exterior material of the battery disposed in the station unit, apply a voltage to the current conductive member, and measure a change in the voltage.

### CROSS-REFERENCE TO RELATED PATENT APPLICATION

The present application claims priority under 35 U.S.C. § 119 (a) to Korean patent application number 10-2024-0061309 filed on May 9, 2024, Korean patent application number 10-2024-0160398 filed on Nov. 12, 2024, and Korean patent application number 10-2025-0052385 filed on Apr. 22, 2025 in the Korean Intellectual Property Office, the entire disclosure of which is incorporated by reference herein.

### BACKGROUND OF THE INVENTION

### 1. Field

The present disclosure relates to a system for inspecting battery and an inspecting method of battery, and specifically, to a system for inspecting battery and an inspecting method of battery capable of quickly and accurately inspecting whether a battery is insulated.

### 2. Description of the Related Art

Secondary batteries are batteries that convert electrical energy into chemical energy and store it so that it can be reused multiple times through charging and discharging. Secondary batteries are widely used throughout the industry due to their economical and eco-friendly characteristics. In particular, lithium secondary batteries are widely used throughout the industry, including portable devices that require high-density energy.

Secondary batteries may be classified into batteries, battery assemblies (e.g., battery modules, battery packs, etc.) according to their units. The battery module may include multiple batteries, and the battery pack may include multiple battery modules.

Defects can occur due to various causes such as physical impact from the outside during the manufacturing process of the secondary battery or defects in the manufacturing process. Such defects in secondary batteries can lead to problems such as explosions and fires. Therefore, there is a need for technology to inspect defects in secondary batteries.

### SUMMARY OF THE INVENTION

According to one aspect of the present disclosure, an object is to provide a system for inspecting battery and an inspecting method of battery.

According to another aspect of the present disclosure, an object is to provide a system for inspecting battery and an inspecting method of battery capable of quickly and accurately inspecting whether a battery is insulative.

According to another aspect of the present disclosure, an object is to provide a system for inspecting battery and an inspecting method of battery capable of inspecting whether a battery is insulative.

Meanwhile, the present disclosure may be used for eco-friendly mobility or the present disclosure may be widely applied in the field of green technology such as electric vehicles, battery charging stations, energy storage systems (ESS), and other battery-based photovoltaics and wind power. In addition, the present disclosure may be used for eco-friendly mobility, including electric vehicles and hybrid vehicles, to prevent climate change by restraining air pollution and greenhouse gas emissions.

In order to solve the above problems, a system for inspecting battery, comprising: a station unit where a battery to be inspected is disposed; and an inspection unit to contact a current conductive member with an exterior material of the battery disposed in the station unit, apply a voltage to the current conductive member, and measure a change in a voltage . . .

According to an embodiment, the system for inspecting battery further comprising: a transfer unit to transfer the battery to the station unit; and a controller to determine whether the exterior material is insulated based on the change in the voltage measured by the inspection unit.

According to an embodiment, the inspection unit may further comprise a constant voltage controller having a first contact tip for applying a voltage to the current conductive member, and measuring the change in the voltage; and a second contact tip for contacting an end portion of the exterior material of the battery.

According to an embodiment, the second contact tip may contact the end portion of the exterior material of the battery, the current conductive member may descend from the top to the bottom to contact a wide surface of the exterior material of the battery, and the constant voltage controller may apply the voltage to the current conductive member through the first contact tip, and the change in the voltage may be transmitted to the controller.

According to an embodiment, the battery may include a pouch-type battery, the exterior material of the battery may comprise at least one sealing portion formed by sealing a pouch sheet, the pouch sheet may comprise at least one conductor layer containing metal, and at least one insulating layer containing a polymer resin, each provided on one side and the other side of the conductor layer, at least a portion of the conductive layer may be exposed through the sealing portion, and the second contact tip may be electrically connected to the conductor layer of the sealing portion.

According to an embodiment, the current conductive member may be an electrically conductive sponge material.

According to an embodiment, the current conductive member may have a shape that covers up to half of the exterior material of the battery.

According to an embodiment, the station unit may comprise a reverser for reversing an arrangement direction of the battery, and the reverser may comprise an adsorption pad for adsorbing the battery.

According to an embodiment, the battery may comprise a first side with a largest area and a second side opposite the first side, the first side of the battery may be contacted with the current conductive member, after the current conductive member may be detached, the reverser may contact the first side of the battery using the adsorption pad to lift the battery, and then rotate the arrangement direction of the battery so that the second side of the battery faces upward, and the current conductive member contacts the second side of the battery.

According to an embodiment, the current conductive member may include a shape of a ‘┐’.

According to an embodiment, the battery may be moved with or without stopping for a predetermined period of time at the station unit.

According to an embodiment, the battery may be moved in a horizontal direction, and the current conductive member may be moved from the top to the bottom to contact with the exterior material of the battery.

An embodiment of the present disclosure provides an inspecting method of battery, comprising: placing a battery to be inspected at a station unit; contacting a current conductive member with an exterior material of the battery and applying a voltage; and measuring a change in an applied voltage.

According to an embodiment, the current conductive member may have a shape that covers up to half of the exterior material of the battery, and the current conductive member may contact the exterior material of the battery at least twice.

According to an embodiment, the placing the battery may further comprise transporting the battery to the station unit using a transfer unit, and the measuring the change in the applied voltage may further comprise determining whether the exterior material is insulated based on the change in the applied voltage.

### BRIEF DESCRIPTION OF THE DRAWINGS

FIG. 1 is a block diagram illustrating a system for inspecting battery according to an embodiment.

FIG. 2 is a schematic diagram of a system for inspecting battery according to an embodiment.

FIG. 3 is a schematic diagram of an inspection process according to an embodiment.

FIGS. 4 and 5 are diagrams schematically illustrating a state in which a battery and a current conductive member are in contact with each other, according to an embodiment.

FIGS. 6 and 7 are cross-sectional views schematically illustrating an inspection process of a battery according to an embodiment.

FIG. 8 is a cross-sectional view schematically illustrating a pouch exterior material according to an embodiment.

FIGS. 9 and 10 are diagrams for explaining a method of determining whether a battery is insulative.

### DETAILED DESCRIPTION

Hereinafter, the present disclosure will be described in detail with reference to the accompanying drawings. This is, however, illustrative only and not intended to limit the disclosure to the specific embodiments illustratively described.

The structural or functional descriptions of the embodiments disclosed in this specification or the application are merely exemplified for the purpose of describing embodiments according to the technical idea of this disclosure, and embodiments according to the technological idea of this disclosure may be implemented in various forms in addition to the embodiments disclosed in the specification or the application, and the technical idea of the disclosure is not to be construed as being limited to the embodiments described in this specification or in the application.

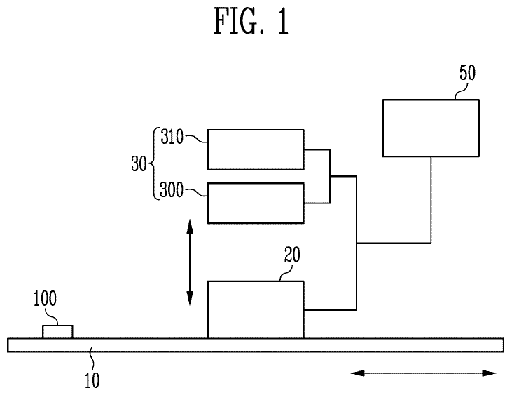

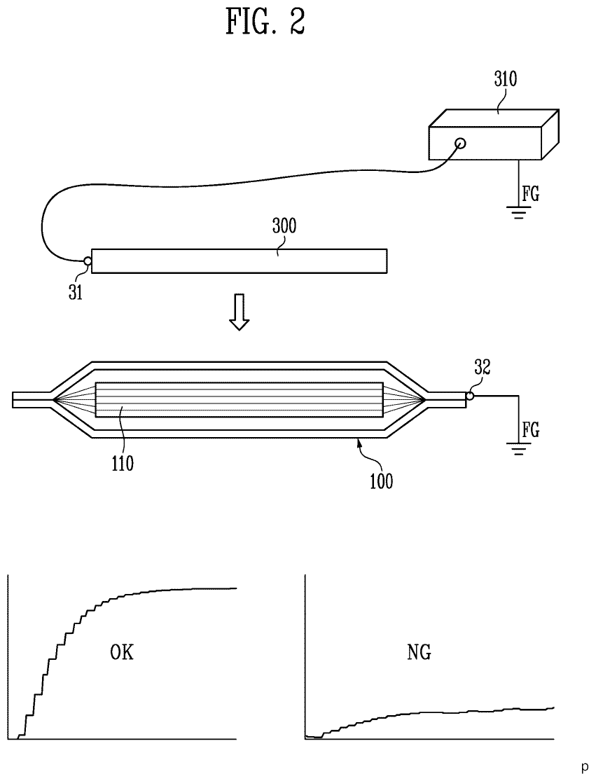

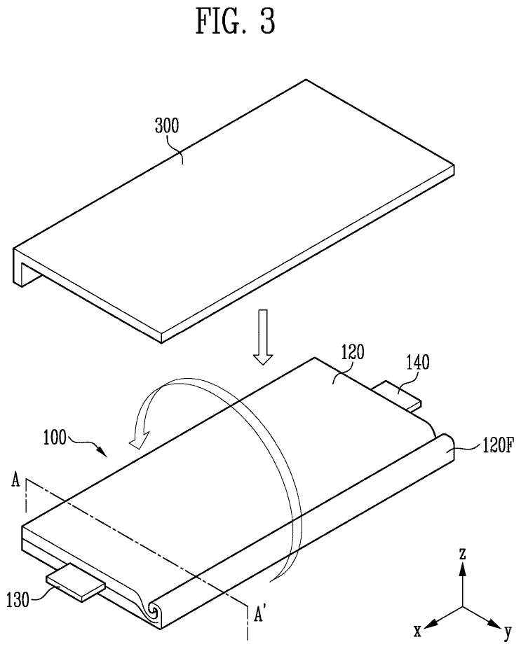

FIG. 1 is a block diagram illustrating a system for inspecting battery according to an embodiment, and FIG. 2 is a schematic diagram of a system for inspecting battery according to an embodiment. FIG. 3 is a schematic diagram of an inspection process according to an embodiment.

Referring to FIGS. 1 to 3, a system for inspecting battery according to an embodiment may comprise: a station unit 20 where a battery 100 to be inspected is disposed; and an inspection unit 30 to contact a current conductive member 300 with an exterior material of the battery disposed in the station unit 20, apply a voltage to the current conductive member 300, and measure a change in the voltage.

According to an embodiment of the present disclosure, the system for inspecting battery may be for inspecting insulation of the battery.

According to an embodiment, the system for inspecting battery may inspect whether the insulation layer of the exterior material of the battery is damaged.

According to an embodiment, the system for inspecting battery may inspect whether the conductor layer of the exterior material of the battery is exposed.

In one embodiment, the system for inspecting battery may be used to inspect the insulation of the battery. Whether or not the insulation of the battery is maintained is an important criterion for determining the defect of the battery, and may be measured at the battery manufacturing stage. In addition, the present invention is not limited thereto, and may be used in an environment in which the insulation properties of the battery need to be measured, such as the use of the battery.

In an embodiment, the battery to be inspected by the system for inspecting battery may be a secondary battery capable of being charged and discharged multiple times. The secondary battery is not limited thereto, but may be, for example, a lithium cobalt battery, a lithium nickel battery, a lithium iron phosphate battery, a lithium ion battery, a lithium polymer battery, a lithium sulfur battery, a nickel hydrogen battery, a nickel cadmium battery, a sodium battery, an all-solid-state battery, or the like.

In an embodiment, the system for inspecting battery may include a transfer unit 10 that transfers the battery 100 to be inspected. The transfer unit 10 can move the battery in a particular direction. For example, the particular direction may be a horizontal direction.

In one embodiment, the transfer unit 10 may comprise a conveyor and a transport motor. The transfer motor may transmit the rotational force to the conveyor. The conveyor may move the battery located at a particular point on the conveyor to another point when the rotational force is transmitted.

Additionally, the system for inspecting battery may further include a controller 50 that determines whether the exterior material is insulated based on the change in the voltage measured by the inspection unit 30.

The controller 50 can determine whether the insulation of the exterior material is normal (OK) or defective (NG). Specifically, when the current conductive member 300 and the battery 100 are in contact with each other, a constant voltage can be applied to the current conductive member 300. At this time, the controller 50 determines that the insulation of the exterior material is normal (OK) if the applied voltage is maintained, and determines that the insulation of the exterior material is defective (NG) if a voltage drop occurs.

In an embodiment, when the system for inspecting battery is used in the battery manufacturing step, the battery assembly process may be performed, and after the aging and degassing processes are completed, the insulation of the battery may be measured in the quality inspection step. Hereinafter, the battery 100 will be described as a reference, but the system for inspecting battery according to the present disclosure may be used to inspect insulation properties of various battery types.

The battery 100 may be classified according to a packaging type of the exterior material, and is not limited thereto, but may be, for example, a pouch-type, a coin type, a cylindrical type, a prismatic type, or the like.

As shown in FIGS. 2 and 3, the battery 100 may be in a form in which the electrode assembly 110 is accommodated in the battery exterior material 120.

The electrode assembly 110 may include a plurality of electrode layers and a separator disposed between the plurality of electrode layers. The plurality of electrode layers may include at least one cathode layer and at least one anode layer.

In one embodiment, the battery 100 may further comprise an electrolyte in the exterior material 120. The electrolyte may include a substance that functions as a medium to help the movement of ions such as lithium ions.

In an embodiment, the station unit 20 may include an inspection area in which a battery to be inspected is disposed. The battery 100 may be transferred to the inspection area of the station unit 20 by the transfer unit 10. Although not limited thereto, the inspection area may be an inspection table placed in a horizontal direction.

In an embodiment, the battery is moved with or without stopping for a predetermined period of time at the station unit. When the battery 100 moves to the inspection area, it may stop for a predetermined time for inspection. In addition, in one embodiment, the battery 100 may be inspected while being moved without stopping in the inspection area.

When the battery 100 is located in the inspection area, the current conductive member 300 may be brought into contact with the battery 100 by the inspection unit 30. The inspection unit 30 may include a constant voltage controller 310 for applying a voltage to the current conductive member 300 and measuring a change in the applied voltage. The constant voltage controller 310 may be connected to the current conductive member 300, and when the current conductive member 300 comes into contact with the battery 100, a voltage may be applied to the current conductive member 300 through the constant voltage controller 310.

In an embodiment, the battery 100 may move in a horizontal direction, and the current conductive member 300 may move in a top and a bottom direction (z-axis direction). The battery 100 to be inspected may be moved in a horizontal direction, and the current conductive member 300 may be moved from the top to the bottom to contact the battery 100. When the inspection is completed, the current conductive member 300 may be raised. The moving direction of the current conductive member 300 is not limited thereto, and the moving direction may be determined according to the type of the battery and the manner in which the battery is disposed in the inspection area.

In one embodiment, the exterior material 120 of the battery may be inspected at least twice. The current conductive member 300 may have a shape corresponding to the shape of the exterior material of the battery. The current conductive member 300 may be formed to cover the entire or a partial area of the battery exterior material. Although not limited thereto, for example, the current conductive member 300 may have a shape that covers up to half of the area of the exterior material of the battery. Accordingly, the entire area of the battery exterior material can be inspected by contacting the battery exterior material twice with the current conductive member.

In an embodiment, when the inspection of one side of the battery is completed, the inspection of the other side of the battery may be performed.

In an embodiment, as shown in FIG. 3, the battery 100 may include a pouch-type battery.

In an embodiment, the pouch-type battery 100 may include a folding portion 120F.

When the pouch sheet is used as the exterior material of the battery, the electrode assembly may be accommodated in the pouch sheet, and the pouch sheet may be sealed and bent to form the folding portion 120F to seal the pouch sheet.

For example, but not limited thereto, the electrode assembly may be placed in a pouch sheet, and the pouch sheet may be folded in half to seal the three sides. The electrode assembly may include electrode leads 130, 140, which may be exposed in the x-axis direction. In this case, the folding portion 120F may be formed by bending a sealing portion to which the electrode leads 130 and 140 are not exposed.

In one embodiment, the current conductive member 300 may be in the shape of a ‘┐’.

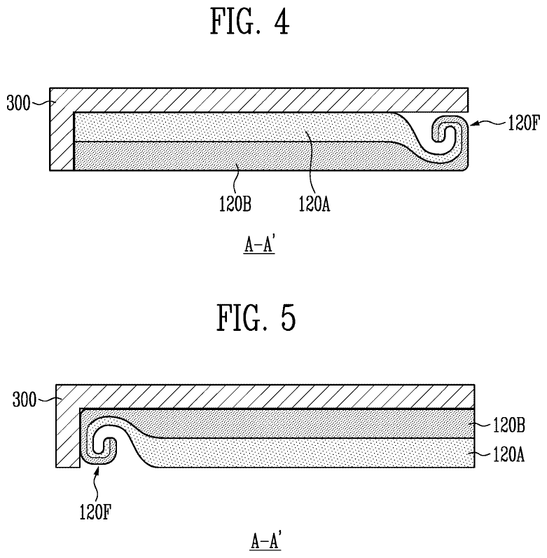

FIGS. 4 and 5 are diagrams schematically illustrating a state in which a battery and a current conductive member are in contact with each other, according to an embodiment. FIGS. 4 and 5 illustrate pouch-type battery, and illustrations of electrode assemblies disposed in the pouch exterior materials 120A and 120B are omitted. The battery may comprise a first side with a largest area and a second side opposite the first side.

Referring to FIG. 3 to FIG. 5, the current conductive member 300 in the shape of a ‘┐’

may be brought into contact with the first side 120A of the battery. The current conductive member 300 may be understood to correspond to a form of a pouch-type battery. The pouch-type battery is formed to cover the first side (top surface) and one side surface, and a cross-section of the current conductive member 300 may have a shape of ‘┐’.

FIGS. 3 to 5 show a pouch-type battery 100, and illustrations of electrode assemblies disposed in the pouch exterior materials 120A and 120B are omitted.

As shown in FIGS. 3 and 4, the current conductive member 300 may be in contact with the first side 120A of the pouch exterior material and one side surface connected to the first side 120A. After inspecting the first side 120A of the pouch exterior material and one side surface connected to the first side, as shown in FIG. 3 and FIG. 5, the battery is reversed in the direction of the arrow, so that the current conductive member 300 can be brought into contact with the second side (bottom surface) 120B of the battery and the one side surface connected with the second side.

In an embodiment, the station unit 20 may be provided with a means for changing an arrangement direction of the battery 100.

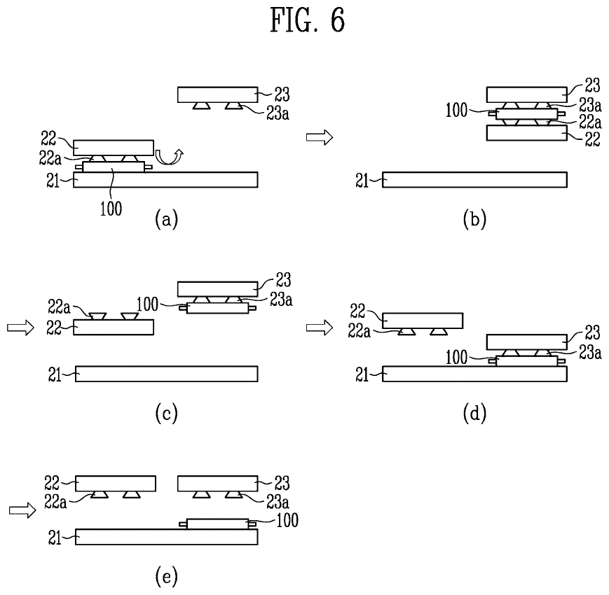

FIG. 6 is a cross-sectional view schematically illustrating an inspection process of a battery according to an embodiment.

Referring to FIG. 6, the station unit 20 may include an inspection table 21. The inspection table 21 may include an inspection area in which a battery to be inspected is disposed. The station unit 20 includes an adsorption pad 22a that is adsorbed to the battery, and may include a reverser 22 that reverses an arrangement direction of the battery. The reverser 22 may include the adsorption pad 22a that is adsorbed to the battery.

The battery may include a first side 120A with the largest area and a second side 120B opposite to the first side 120A. The first side 120A of the battery may be contacted with the current conductive member 300. After measuring whether the first side 120A of the battery in contact with current conductive member 300 is insulated, the current conductive member 300 may be detached. After the current conductive member 300 is detached, the reverser 22 may contact the first side 120A of the battery using the adsorption pad 22a to lift the battery, and then rotate the arrangement direction of the battery so that the second side of the battery faces upward. The adsorption pad 22a provided on the reverser 22 can securely fix the battery when lifting it.

The reverser 22 may switch the arrangement direction of the battery so that the second side (bottom surface) 120B of the battery faces upward. At this time, the adsorption pad 22a provided on the reverser 22 come into contact with first side 120A of the battery, securely fixing the battery in place. The second side 120B of the battery is exposed toward the upper side, and the current conductive member 300 can come into contact with the second side 120B of the battery.

As shown in (a) of FIG. 6, when the battery 100 is placed on the inspection table 21, the reverser 22 may lift the battery 100 to reverse the upper and lower surfaces of the battery cell 100 after inspecting one surface of the battery. The reverser 22 may be provided with an adsorption pad 22a, and the adsorption pad 22a may adsorb the battery 100 to move the battery 100. As shown in (b) and (C) of FIG. 6, the reverser 22 to which the battery 100 is adsorbed may reverse the upper and lower surfaces of the battery 100, place the battery 100 in the pick and place 23, and return to the place. As shown in (d) and (e) of FIG. 6, the pick-and-place 23 may be provided with an adsorption pad 23a, and the adsorption pad 23a may adsorb the battery 100, place the battery 100 on the inspection table 21, and then return to the place. The inspection can be carried out by bringing the current conductive member into contact with the other surface of the battery placed on the inspection table 21.

FIG. 7 is a cross-sectional view schematically illustrating an inspection process of a battery according to an embodiment.

Referring to FIG. 7, the station unit 20 may include an inspection table 21. The inspection table 21 may include an inspection area in which a battery to be inspected is disposed.

As shown in (a) and (b) of FIG. 7, when the battery 100 is disposed on the inspection table 21, the reverser 22 may lift the battery 100 to reverse the upper and lower surfaces of the battery 100 after inspecting one surface of the battery. The reverser 22 may be provided with an adsorption pad 22a, and the adsorption pad 22a may adsorb the battery 100 to reverse the battery 100. As shown in (b) of FIG. 7, the reverser 22 to which the battery 100 is adsorbed may reverse the upper and lower surfaces of the battery 100 to expose the other surfaces of the battery 100. The inspection may be performed by bringing the current conductive member into contact with the second side 120B of the exposed battery.

According to an embodiment, the current conductive member 300 has a shape of ‘┐’, so that the entire area of the pouch-type battery can be inspected in at least twice.

In addition, although not shown, the shape of the current conductive member 300 is not particularly limited, and may be appropriately modified according to the shape of the battery. The current conductive member 300 may have a shape that surrounds the outer shape of the battery.

According to an embodiment, the current conductive member 300 may be a sponge material through which electricity flows. Due to the nature of the sponge material having elasticity, damage to the pouch exterior can be minimized even if it comes into contact with the pouch exterior as closely as possible. In addition, the folding portion 120F of the pouch exterior material can be easily wrapped. That is, even if the shape of the pouch exterior material is not flat and includes a curved portion, the current conductive member 300 made of a sponge material can easily come into contact with a curved region.

In an embodiment, the electrical signal of the battery 100 may be measured by applying a voltage after the current conductive member 300 is brought into contact with the battery 100. Referring to FIG. 2, the inspection unit 30 may include a constant voltage controller 310 and may include first and second contact tips 31, 32 in contact with the current conductive member 300 and the battery 100.

In an embodiment, the inspection unit 30 may further comprise the constant voltage controller 310 having a first contact tip 31 for applying a voltage to the current conductive member 300, and measuring the change in the voltage; and a second contact tip 32 for contacting an end portion of the exterior material of the battery.

The second contact tip 32 may contact the end portion of the exterior material of the battery, the current conductive member 300 may descend from the top to the bottom to contact a wide surface of the exterior material of the battery. The constant voltage controller 310 applies the voltage to the current conductive member 300 through the first contact tip 31, and the change in the voltage is transmitted to the controller 50.

In an embodiment, the current conductive member 300 may be connected to the constant voltage controller 310, and when the current conductive member 300 comes into contact with the battery 100, a voltage may be applied to the current conductive member 300 through the constant voltage controller 310. In one embodiment, the first contact tip 31 may be connected to the current conductive member 300 to measure a voltage change.

In one embodiment, the second contact tip 32 may be connected to an exterior material of the battery. Specifically, the second contact tip 32 may be electrically connected to the exposed conductive layer of the sealing portion of the exterior material of the battery.

More specifically, the constant voltage controller 310 may be connected to the first contact tip 31 via the current conductive member 300 to form a positive contact (+), and the exterior material of the battery may be connected to the second contact tip 32 to form a negative contact (−). When the constant voltage controller 310 may apply a constant voltage, voltage maintenance or voltage drop may occur, and the criteria for determining voltage maintenance and voltage drop may be the voltage between the second contact tip 32 in contact with the current conductive member 300 and the exterior material of the battery. Here, when determining the exterior material of the battery, the controller may determine voltage maintenance as normal (OK) and voltage drop as abnormal (NG).

The first and second contact tips 31 and 32 can detect an electrical signal of the battery and determine whether the battery is insulated by the generated waveform.

In an embodiment, whether the battery is insulated can be determined by measuring a change in the applied voltage.

The exterior material of the battery may comprise at least one sealing portion formed by sealing pouch sheet. The sealing portion may be formed by heat pressing the outer periphery after providing an electrode assembly and an electrolyte inside.

The pouch sheet may comprise at least one conductor layer containing metal, and at least one insulating layer containing a polymer resin, each provided on one side and the other side of the conductor layer. At least a portion of the conductive layer is exposed through the sealing portion, and the second contact tip is electrically connected to the conductor layer of the sealing portion.

In an embodiment, the electrical signal may be due to an arc discharge.

The arc discharge is when a certain voltage is applied to the positive and negative terminals, electrons in the air between them are separated and the air is ionized, and the separated electrons accelerate with great energy due to the strong voltage, and more electrons can be separated by colliding with surrounding atoms. It can mean that the air, which is an insulator, changes into a state in which electricity can pass through due to a large amount of charge.

In this case, if the conductor layer of the exterior material, for example, the aluminum layer, is exposed, the discharge phenomenon may occur through the aluminum through the air that has become electrically conductive. On the other hand, if the conductor layer of the exterior material may be covered with an insulating layer and is not exposed, no discharge occurs.

Specifically, in the state of arc discharge, when the conductor layer is not exposed on the pouch exterior material 120A and 120B, that is, when the pouch exterior material 120A and 120B are covered with the insulating layer, the voltage applied to the current conductive member 300 may be maintained because no current flows between the current conductive member 300 and the pouch exterior material 120A and 120B. On the other hand, if the conductor layers are exposed to the pouch exterior material 120A and 120B, current flows into the air between the current conductive member 300 and the conductor layers of the pouch exterior material 120A and 120B and a voltage drop may occur. Therefore, when the applied voltage drops, it can be determined that the insulating property of the pouch exterior material is broken, and when the applied voltage is maintained, it can be judged that the insulating property is maintained, that is, normal.

More specifically, the current conductive member 300 may be an electrically conductive sponge material. The current conductive member 300 may be a sponge material containing multiple pores, and the air contained within the pores of the sponge material may be ionized by arc discharge. In this way, the ionized air containing electrons may be contained within the pores of the sponge material, enabling more effective verification of whether the insulation of the exterior material in contact with the current conductive member 300 has been damaged.

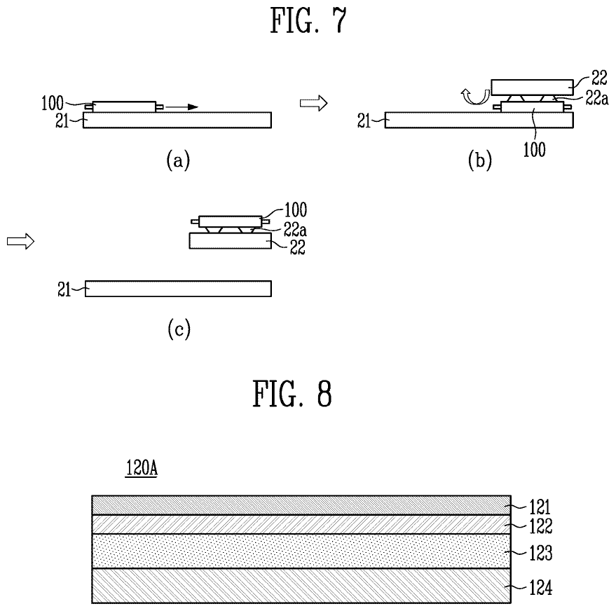

FIG. 8 is a cross-sectional view schematically illustrating a pouch exterior material 120A according to an embodiment.

In an embodiment, the first side 120A of the pouch exterior material may include first insulating layers 121 and 122, a conductor layer 123, and a second insulating layer 124.

The conductor layer 123 may be included to maintain the shape of the battery and prevent moisture penetration, and an insulating layer may be formed on one surface and the other surface of the conductor layer 123 to control the electrical characteristics of the battery.

For example, but not limited to, the first side 120A of the pouch exterior material include first insulating layers 121 and 122, a conductor layer 123, and a second insulating layer 124.

The first insulating layers 121 and 122 are formed on one surface of the conductor layer 123 to prevent the conductor layer 123 from being exposed to the outside. For example, but not limited thereto, the first insulating layers 121 and 122 may be formed of PET (polyethylene) or nylon material. Although not limited thereto, for example, the first insulating layers 121 and 122 may be formed to have a thickness of 10 to 30 μm. The PET layer is formed on the outermost part and can play a role in blocking moisture and maintaining surface rigidity. The nylon layer protects the battery from external impacts and can be used to maintain insulation and heat resistance.

The conductor layer 123 may be formed of a metal material, but is not limited thereto, and may be formed of, for example, aluminum. Although not limited thereto, for example, the conductor layer 123 may be formed to have a thickness of 30 to 50 μm.

The second insulating layer 124 may be formed on the other surface of the conductor layer 123, and contact between the electrode assembly and the conductor layer 123 may be prevented. Although not limited thereto, for example, the second insulating layer 124 may be formed of a material of PP (polypropylene). Although not limited thereto, for example, the second insulating layer 124 may be formed to have a thickness of 50 to 100 μm. The polypropylene layer is excellent in moldability and thermal adhesion, and can be used for heat resistance, waterproofness, and electrolytic solution resistance.

In one embodiment, the second contact tip 32 may be connected to the conductor layer 123 of the pouch exterior material.

The electrical signal obtained from the conductor layer 123 can be used to determine whether the pouch exterior material 120A and 120B are insulation broken.

In an embodiment, the conductor layer 123 may be exposed on the side of the pouch exterior material in the direction in which the electrode leads 130 and 140 are exposed.

In the case of pouch-type battery, they can be formed by folding the pouch sheet and sealing the overlapped pouch sheet after receiving the electrode assembly. The pouch sheet may be sealed on three sides except for the folded portion, and the side surface of the pouch sheet may be exposed in the portion where the folding portion 120F is not formed. Accordingly, the conductor layer 123 located in the middle of the pouch sheet is exposed, and the contact tip 400 can be connected to the conductor layer 123.

The electrical signal of the pouch exterior can be measured by connecting the second contact tip 32 to the exposed conductor layer 123.

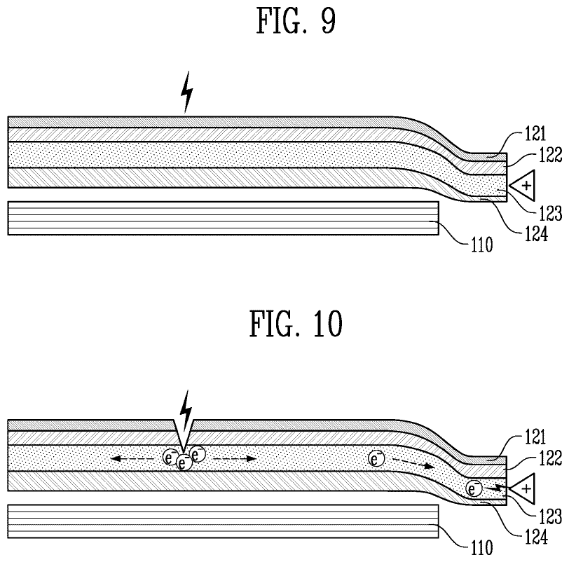

FIGS. 9 and 10 are diagrams for explaining a method of determining whether a battery is insulative.

As shown in FIG. 9, when the conductor layer 123 is not exposed, the current does not flow between the current conductive member 300 and the first side 120A of the pouch exterior material, so the voltage applied to the current conductive member 300 can be maintained.

On the other hand, if the conductor layer 123 is exposed to the first side 120A of the pouch exterior material as shown in FIG. 10, current flows into the air between the current conductive member 300 and the conductor layer 123 of the first side 120A of the pouch exterior material, and a voltage drop may occur.

In this way, when the voltage applied to the current conductive member 300 drops, it may be determined that the insulation of the pouch exterior material is destroyed.

In this embodiment, the first side 120A of the pouch outer material has been described, but the same applies to the second side 120B of the pouch outer material.

In an embodiment, the system for inspecting battery may include a controller 50. The overall operation of the system for inspecting battery can be controlled by the controller 50. Further, the controller 50 may determine whether the outer material is insulated by a change in the voltage applied to the current conductive member 300 in the inspection unit.

In an embodiment, the controller 50 may control the operation of at least one of the transfer unit 10, the station unit 20, and the inspection unit 30.

When the insulation test of the battery is completed, the battery can be moved to another position by the transfer unit 10.

As described above, in an embodiment, when the battery 100 moves to the station unit 20, the battery 100 may be stopped for a predetermined time for inspection, or the inspection may proceed while being moved without being stopped by the station unit 20.

According to an embodiment, since the inspection is performed by the contact between the current conductive member and the battery, the inspection time is not long, so that the inspection may be performed while moving the battery without stopping the battery to be inspected by the station unit. As such, it is possible to perform battery inspections while responding to the speed of battery mass production.

An inspecting method of battery according to an embodiment of the present disclosure may comprise: placing a battery to be inspected at a station unit; contacting a current conductive member with an exterior material of the battery and applying a voltage; and measuring a change in an applied voltage.

The inspecting method of battery according to an embodiment of the present disclosure may use the system for inspecting battery described above.

According to an embodiment, the placing the battery further comprise transporting the battery to the station unit using a transfer unit. For example, the transfer unit may include a conveyor belt and may continuously transfer batteries to the station unit.

According to an embodiment, first, the battery 100 to be inspected may be transferred to the inspection area. Although not limited thereto, for example, the battery 100 to be inspected may be transported in a horizontal direction.

As shown in FIGS. 2 and 3, when the battery to be inspected is located in the inspection area, the current conductive member 300 may be brought into contact with the battery exterior material and a voltage may be applied thereto.

In an embodiment, when the battery moves to the inspection area, the battery may stop for a predetermined time for inspection, or the battery may not stop in the inspection area, and the inspection may proceed while being moved.

In an embodiment, the battery to be inspected may be a pouch-type battery 100.

In an embodiment, the battery 100 may move in a horizontal direction, and the current conductive member 300 may move from the top to the bottom (z-axis direction) to contact the battery 100. When the inspection is completed, the current conductive member 300 may be raised.

The moving direction of the current conductive member 300 is not limited thereto, and the moving direction may be determined according to the type of the battery and the manner in which the battery is disposed in the inspection area.

In an embodiment, the inspection of the battery exterior material may be performed twice. The current conductive member 300 may have a shape corresponding to the shape of the battery exterior material, and may be formed to cover all or a partial area of the battery exterior materials. Although not limited thereto, for example, the current conductive member 300 may have a shape that covers up to ½ of the area of the battery exterior material. Accordingly, the entire area of the battery exterior material can be inspected by contacting the battery exterior material twice with the current conductive member.

According to an embodiment, the measuring the change in the applied voltage may further comprise determining whether the exterior material is insulated based on the change in the applied voltage.

In an embodiment, when a voltage is applied after the current conductive member 300 is brought into contact with the pouch exterior material, the electrical signal of the pouch exterior material may be measured by the constant voltage controller 310. The electrical signal can be used to determine whether the pouch exterior is insulated. The determination of insulation may be performed by measuring whether the voltage applied to the pouch exterior material has changed.

If the applied voltage is maintained, it can be determined that the insulation of the pouch exterior material is normal, and if the applied voltage drops, it can be judged that the insulation of a pouch exterior material is broken.

According to an embodiment, since the inspection is performed by the contact between the current conductive member and the battery, the inspection time is not long, so that the inspection may be performed while moving the battery without stopping the battery to be inspected by the station unit. As such, it is possible to perform battery inspections while responding to the speed of battery mass production.

In general, whether or not the battery exterior material is exposed to the conductor layer is performed by manual inspection using a lupe. When a worker puts the lupe on a scratched area and sees a bright metallic color, it is treated as a defect. However, it is difficult to define a bright metallic color, and it may be less reliable because it depends on the subjective judgment of the worker whether it is defective or not. In addition, if the scratches on the insulating layer are very small, the amount of light reflected is small, so it may not be observed with the lupe. In addition, manual inspections by workers can significantly reduce productivity in high-speed mass production lines.

In addition, a method of determining whether the conductor layer is exposed using brine (salt water) is used. After applying brine to the damaged insulation layer and allowing brine to seep into the pouch exterior, apply a probe to the area where brine is buried and the energized area of the pouch exterior to check the insulation resistance. If the insulation resistance is less than or equal to the reference value, it is determined that the pouch exterior material is damaged. However, applying and purifying brine to each damaged area has the disadvantage of not being able to cope with the speed of the mass production line. In addition, since brine is applied by specifying the area that is judged to be damaged, there is a possibility that areas that do not show damage in appearance may be omitted from the inspection.

In addition, there is also a method of determining whether the conductor layer is exposed using plasma, but this requires a separate gas supply to generate plasma, thereby increasing production costs. In addition, depending on the shape of the nozzle to which the plasma is sprayed, there is a possibility of undetected if the plasma does not touch the damaged part of the pouch exterior material.

In contrast, the system for inspecting battery and the inspecting method of battery according to an embodiment of the present disclosure can quickly and accurately inspect whether the exterior material of the battery is damaged.

According to an embodiment of the present disclosure, it is possible to quickly and accurately check whether the exterior material of the battery is insulating.

According to another embodiment of the present disclosure, it is possible to quickly and accurately check whether the exterior material of the battery is insulating.

According to another embodiment of the present disclosure, it is possible to quickly and accurately check whether a pouch-type battery is insulative.

According to another embodiment of the present disclosure, it is possible to quickly and accurately check whether the pouch exterior material of the battery is insulating.

The present disclosure may be implemented in various forms, and the scope of rights is not limited to the above-described embodiments. Therefore, if the modified embodiment includes the elements of the claims of the present disclosure, it should be considered to fall within the scope of the present disclosure.

What is claimed is:

1. A system for inspecting battery, comprising:
a station unit where a battery to be inspected is disposed; and
an inspection unit to contact a current conductive member with an exterior material of the battery disposed in the station unit, apply a voltage to the current conductive member, and measure a change in a voltage.

2. The system for inspecting battery according to claim 1, further comprising:
a transfer unit to transfer the battery to the station unit; and
a controller to determine whether the exterior material is insulated based on the change in the voltage measured by the inspection unit.

3. The system for inspecting battery according to claim 2,
wherein the inspection unit further comprises a constant voltage controller having a first contact tip for applying a voltage to the current conductive member, and measuring the change in the voltage; and a second contact tip for contacting an end portion of the exterior material of the battery.

4. The system for inspecting battery according to claim 3,
wherein the second contact tip contacts the end portion of the exterior material of the battery, the current conductive member descends from the top to the bottom to contact a wide surface of the exterior material of the battery, and
wherein the constant voltage controller applies the voltage to the current conductive member through the first contact tip, and the change in the voltage is transmitted to the controller.

5. The system for inspecting battery according to claim 4,
wherein the battery includes a pouch-type battery,
wherein the exterior material of the battery comprises at least one sealing portion formed by sealing a pouch sheet,
wherein the pouch sheet comprises at least one conductor layer containing metal, and at least one insulating layer containing a polymer resin, each provided on one side and the other side of the conductor layer,
wherein at least a portion of the conductive layer is exposed through the sealing portion, and
wherein the second contact tip is electrically connected to the conductor layer of the sealing portion.

6. The system for inspecting battery according to claim 1, wherein the current conductive member is an electrically conductive sponge material.

7. The system for inspecting battery according to claim 1, wherein the current conductive member has a shape that covers up to half of the exterior material of the battery.

8. The system for inspecting battery according to claim 1, wherein the station unit comprises a reverser for reversing an arrangement direction of the battery, and the reverser comprises an adsorption pad for adsorbing the battery.

9. The system for inspecting battery according to claim 8, wherein
wherein the battery comprises a first side with a largest area and a second side opposite the first side,
wherein the first side of the battery is contacted with the current conductive member,
after the current conductive member is detached, the reverser contacts the first side of the battery using the adsorption pad to lift the battery, and then rotates the arrangement direction of the battery so that the second side of the battery faces upward, and
wherein the current conductive member contacts the second side of the battery.

10. The system for inspecting battery according to claim 1, wherein the current conductive member includes a shape of a ‘┐’.

11. The system for inspecting battery according to claim 1, wherein the battery is moved with or without stopping for a predetermined period of time at the station unit.

12. The system for inspecting battery according to claim 1, wherein the battery is moved in a horizontal direction, and the current conductive member is moved from the top to the bottom to contact with the exterior material of the battery.

13. An inspecting method of battery, comprising:
placing a battery to be inspected at a station unit;
contacting a current conductive member with an exterior material of the battery and applying a voltage; and
measuring a change in an applied voltage.

14. The inspecting method of battery according to claim 13, wherein the current conductive member has a shape that covers up to half of the exterior material of the battery, and the current conductive member contacts the exterior material of the battery at least twice.

15. The inspecting method of battery according to claim 13,
wherein the placing the battery further comprises transporting the battery to the station unit using a transfer unit, and
wherein the measuring the change in the applied voltage further comprises determining whether the exterior material is insulated based on the change in the applied voltage.
